(19) United States
(12) Patent Application Publication
(10) Pub. No.: US 2025/0113518 A1
(43) Pub. Date: Apr. 3, 2025

(54) Doping for Superjunction Device

(71) Applicant: Infineon Technologies Austria AG, Villach (AT)

(72) Inventors: Christian Fachmann, Villach (AT); Franz Hirler, Isen (DE); Maximilian Treiber, München (DE)

(21) Appl. No.: 18/897,345

(22) Filed: Sep. 26, 2024

Related U.S. Application Data
(60) Provisional application No. 63/541,635, filed on Sep. 29, 2023.

(51) Int. Cl. H01L 29/66; H01L 21/265; H01L 27/088; H01L 29/06; H01L 29/78

(52) U.S. Cl. CPC H10D 30/0297; H01L 21/265; H10D 30/668; H10D 62/111; H10D 84/83

(57) ABSTRACT

A method of forming a semiconductor includes forming a superjunction structure comprising a plurality of superjunction columns that alternate in conductivity type along a lateral direction of the semiconductor substrate; and forming a plurality of transistor cells in an active area of the semiconductor substrate, each of the transistor cells being configured to control a vertical current flowing through superjunction structure, wherein forming the transistor cells includes forming source regions and body regions below the source regions; wherein forming the body regions includes forming a body layer extending from a main surface of the semiconductor substrate, wherein a dopant profile of second conductivity type dopants in the body layer increases moving from the main surface into the semiconductor substrate until it reaches a maximum at first depth from the main surface, and wherein the first depth is below a bottom depth of the source regions.

### BACKGROUND

Power semiconductor devices conduct a high load current and withstand a high blocking voltage. Superjunction devices are power semiconductor devices that include a superjunction structure with oppositely doped columns formed in a drift zone which is electrically arranged in series to controllable device channels. When a blocking voltage is applied to a superjunction configured device, a lateral electric field rises and clears out the mobile charge carriers along the vertical p-n junctions between the oppositely doped columns. A space charge begins to expand perpendicularly to the direction of a load current flow in the on-state. The mobile charge carriers are completely forced out of the superjunction structure at a comparatively low blocking voltage. When the blocking voltage is further increased, the depleted superjunction structure acts as a quasi-intrinsic layer and the vertical electric field rises. The breakdown voltage is decoupled from the dopant concentrations in the superjunction structure such that the dopant concentration in the superjunction structure can be comparatively high. Therefore, superjunction devices typically combine very low on-state resistance with high blocking capability. The more closely matched the oppositely doped columns are in dopant concentration, the greater efficiency of the superjunction structure in terms of blocking capability and semiconductor volume is realized.

There is a need to improve superjunction devices and techniques for forming superjunction devices.

### SUMMARY

According to an embodiment, a method of forming a semiconductor device comprises forming a semiconductor substrate with a superjunction structure, the superjunction structure comprising a plurality of superjunction columns that alternate in conductivity type along a lateral direction of the semiconductor substrate; and forming a plurality of transistor cells in an active area of the semiconductor substrate, each of the transistor cells being configured to control a vertical current flowing through the superjunction structure, wherein forming the transistor cells comprises forming source regions extending to a main surface of the semiconductor substrate and body regions at least partially below the source regions, the source regions being first conductivity type regions and the body regions being second conductivity type regions; wherein forming the body regions comprises forming a body layer extending from a main surface of the semiconductor substrate, wherein a dopant profile of second conductivity type dopants in the body layer increases moving from the main surface into the semiconductor substrate until it reaches a maximum at first depth from the main surface, and wherein the first depth is below a bottom depth of the source regions.

According to another embodiment, a method of forming a semiconductor device comprises forming a semiconductor substrate with a superjunction structure, the superjunction structure comprising a plurality of superjunction columns that alternate in conductivity type along a lateral direction of the semiconductor substrate; and forming a plurality of transistor cells in an active area of the semiconductor substrate, each of the transistor cells being configured to control a vertical current flowing through superjunction structure, wherein forming the transistor cells comprises forming a plurality of gate trenches in a main surface of the semiconductor substrate, forming body regions adjacent the gate trenches, and forming body enhancement regions that are laterally spaced apart from the gate trenches, the body enhancement regions having a higher second conductivity type dopant concentration than the body regions, wherein forming the body regions and forming the body enhancement regions comprises forming a body layer that extends from the main surface into the semiconductor substrate and has a baseline second conductivity type doping throughout the body layer and forming partially compensated regions of the body layer wherein the baseline second conductivity type doping is partially compensated by first conductivity type dopants, wherein the body enhancement regions are provided by uncompensated parts of the body layer having the baseline second conductivity type doping, and wherein the body regions are formed by the partially compensated regions of the body layer.

According to an embodiment, a semiconductor device comprises a semiconductor substrate with a superjunction structure, the superjunction structure comprising a plurality of superjunction columns that alternate in conductivity type along a lateral direction of the semiconductor substrate; and a plurality of transistor cells in an active area of the semiconductor substrate, each of the transistor cells being configured to control a vertical current flowing through superjunction structure, wherein the transistor cells each comprise source regions extending to a main surface of the semiconductor substrate and body regions at least partially below the source regions, the source regions being first conductivity type regions and the body regions being second conductivity type regions; wherein for each of the body regions a dopant profile of second conductivity type dopants increases moving from the main surface into the semiconductor substrate until it reaches a maximum at first depth from the main surface, and wherein the first depth is below a bottom depth of the source regions.

According to another embodiment, a semiconductor device comprises a semiconductor substrate with a superjunction structure, the superjunction structure comprising a plurality of superjunction columns that alternate in conductivity type along a lateral direction of the semiconductor substrate; and a plurality of transistor cells in an active area of the semiconductor substrate, each of the transistor cells being configured to control a vertical current flowing through superjunction structure, a body layer extending from a main surface of the semiconductor substrate in the active area and having a baseline second conductivity type doping, wherein the transistor cells comprise a plurality of gate trenches in a main surface of the semiconductor substrate, body regions adjacent the gate trenches, and body enhancement regions that are laterally spaced apart from the gate trenches, the body enhancement regions having a higher second conductivity type dopant concentration than the body regions, wherein the body enhancement regions are formed by portions of the body layer having the baseline second conductivity type doping, and wherein the body regions are formed by partially compensated regions of the body layer wherein the baseline second conductivity type doping is partially compensated by first conductivity type dopants.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a superjunction configured power semiconductor device, according to an embodiment.

FIG. 2 illustrates a close-up view of the upper portion of a transistor cell from a superjunction configured power semiconductor device, according to an embodiment.

FIG. 3 illustrates a plan view layout of the gate trenches and doped semiconductor regions, according to an embodiment.

FIG. 4, which includes FIGS. 4A, 4B and 4C, illustrates selected method steps in a method of forming a semiconductor device, according to an embodiment.

FIG. 5 illustrates a close-up view of the upper portion of a transistor cell from a superjunction configured power semiconductor device, according to another embodiment.

FIG. 6 illustrates a plan view layout of the gate trenches and doped semiconductor regions, according to another embodiment.

FIG. 7, which includes FIGS. 7A, 7B and 7C, illustrates selected method steps in a method of forming a semiconductor device, according to another embodiment.

### DETAILED DESCRIPTION

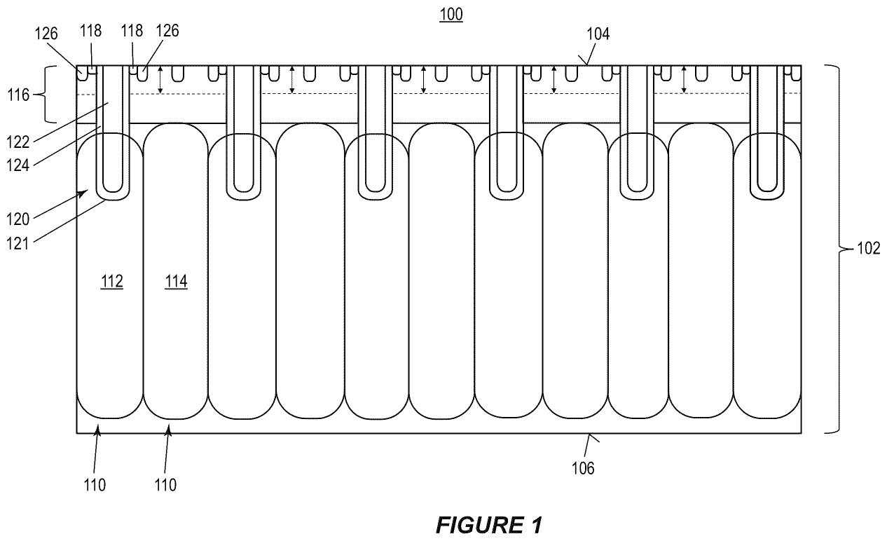

Referring to FIG. 1, a superjunction configured power semiconductor device 100 is depicted, according to an embodiment. The semiconductor device 100 is formed in a semiconductor body 102. The semiconductor body 102 may be formed from a single-crystalline semiconductor material such as silicon (Si), silicon carbide (SiC), germanium (Ge), a silicon germanium crystal (SiGe), gallium nitride (GaN), gallium arsenide (GaAs), etc. The semiconductor body 102 comprises a main surface 104 and a rear surface 106 opposite from the main surface 104, each of which may be substantially planar surfaces.

The semiconductor device 100 is configured as a superjunction device. Examples of superjunction device corresponding techniques for forming semiconductor superjunction device structures are disclosed in U.S. Pat. Nos. 10,084,038B2, 10,468,479B2, 11,211,483B2, and 11,329,126B2 the content of each document being incorporated by reference herein in its entirety. Superjunction devices are also known as compensation devices. The compensation principle is based on a mutual compensation of charges in n-doped and p-doped regions, which are often also referred to as n-doped and p-doped pillar or column regions, in the drift zone of a vertical transistor device such as a vertical MOSFET. To this end, the semiconductor device 100 comprises a superjunction structure with a plurality of superjunction columns 110 disposed within an active region of the semiconductor body 102. The superjunction columns 110 alternate in conductivity type along a lateral direction of the semiconductor body 102. That is, the superjunction structure comprises first conductivity type columns 112 and second conductivity type columns 114 with an opposite conductivity type as the first conductivity type columns 112 arranged alternatingly with one another along the lateral direction of the semiconductor body 102. The first conductivity type columns 112 may be n-type columns and the second conductivity type columns 114 may be p-type columns, for example. The superjunction columns 110 may be regularly spaced apart from one another at a preselected pitch. Each of the superjunction columns 110 may be elongated in plan-view and may have the form of a stripe that extends into the plane of the drawing.

Generally speaking, the semiconductor device 100 can be configured as any type of vertical power semiconductor device 100, e.g., MOSFET (metal oxide semiconductor field effect transistor), IGBT, diode, etc. In the below description, the semiconductor device 100 is configured as a MOSFET. Accordingly, the instant application uses the term source and body when referring to the first and second load terminal regions of the device, i.e., the regions that conduct a load current and maintain a blocking voltage. In the case of different device configurations, different terms may describe corresponding first and second load terminal regions of the device, i.e., the emitter and collector may correspond to the first and second load terminal regions in the case of an IGBT, the anode and cathode may correspond to the first and second load terminal regions in the case of a diode. Further, the person having ordinary skill will recognize that the different device configurations may be realized through appropriate modification of the cell structure, e.g., an IGBT may be realized by providing a doped contact layer with an opposite conductivity type as the drift region at the rear surface 106 of the device, a diode may be realized by omitting gate structures and/or source regions. The concepts disclosed below and benefits flowing therefrom are equally applicable to any one of these variations of a superjunction configured device.

The semiconductor device 100 comprises a plurality of transistor cells formed within an active area of the semiconductor substrate. The active area may be surrounded by an edge or termination region without active transistor cells. The edge or termination region cannot be seen in the view of FIG. 1. The edge termination may comprise one or more features designed to relax the electric field and prevent breakdown occurring at the lateral chip edge.

The semiconductor device 100 comprises a body layer 116 extending from a main surface 104 of the semiconductor substrate into the semiconductor body 102. The body layer 116 is a second conductivity type layer (e.g., a p-type layer) that forms the body regions for each of the transistor cells. The semiconductor device 100 comprises source regions 118 of the first conductivity type (e.g., n-type) that extend to the main surface 104 and are arranged above the body regions. The semiconductor device 100 comprises a gate structure 120 for each of the transistor cells. The gate structures 120 comprise gate trenches 121 that extend into the main surface 104 of the semiconductor substrate. Each of the gate trenches 121 comprise an electrically conductive gate electrode 122 and a gate dielectric 124 that electrically insulates the gate electrode 122 from the adjacent semiconductor material. In a commonly known manner, the gate electrodes 122 are configured to control a channel in the body regions and thereby control a vertical current flowing between the main and rear surfaces 104, 106 of the semiconductor substrate.

The source regions 118 and the body regions of the semiconductor device 100 may be electrically connected to a source potential electrode (not shown) formed over the main surface 104 of the semiconductor body 102. This electrical connection may be effectuated with body contacts (not shown) that extend into the main surface 104 of the main surface 104 of the semiconductor substrate 102. These body contacts are formed in body contact trenches that form an ohmic connection with the body layer 116 and with the source regions 118. The semiconductor device 100 comprises body enhancement regions 126 formed underneath the body contact trenches. The body enhancement regions 126 are second conductivity type regions with a higher dopant concentration than the underlying dopant concentration of the body layer 116, thereby facilitating a low ohmic contact with the body contacts. The gate electrodes 122 may each be electrically connected to a gate potential electrode (not shown) formed over the main surface 104 of the semiconductor substrate 102. The drain regions of the device may be provided by a first conductivity type layer at the rear surface 106 of the semiconductor substrate 102 and electrically connected to a drain potential electrode (not shown).

The superjunction structure comprising the superjunction columns 110 is arranged below the source regions 118 and the body regions of the transistor cells. The superjunction structure is configured such that, in the off-state of the device, the charges of the superjunction columns 110 can be mutually depleted and that, in the activated state or on-state, an uninterrupted, low-ohmic conduction path is formed between the source potential electrode at the main surface 104 and the drain potential electrode at the rear surface 106. By virtue of the compensation of the p-type and n-type dopants of the superjunction columns 110 of the superjunction structure, the doping of the current-carrying region is increased, which results in a significant reduction of the on-state resistance Ron despite the reduction in the a current-carrying area.

The superjunction columns 110 may be formed by building up the semiconductor body 102 by epitaxially depositing a plurality of layers sequentially onto a substrate, such as a silicon single crystal, and by forming discrete doped zones including donors or acceptors in each of the layers to form laterally alternate stacks of discrete zones of the same conductivity type, i.e., stacks of discrete zones comprising donors are interleaved with stacks of discrete zones comprising acceptors. A column of a particular conductivity type is formed from the stack of discrete zones by a subsequent diffusion process. In order that the superjunction columns 110 of opposing conductivity types are mutually depleted in the off-state, the doping concentration of the superjunction columns 110 of opposing conductivity types may be selected to be identical or at least within close range of identical. In an embodiment, the doping concentration of the superjunction columns 110 within the active region of the device is set to be as identical as is practically achievable by processing techniques.

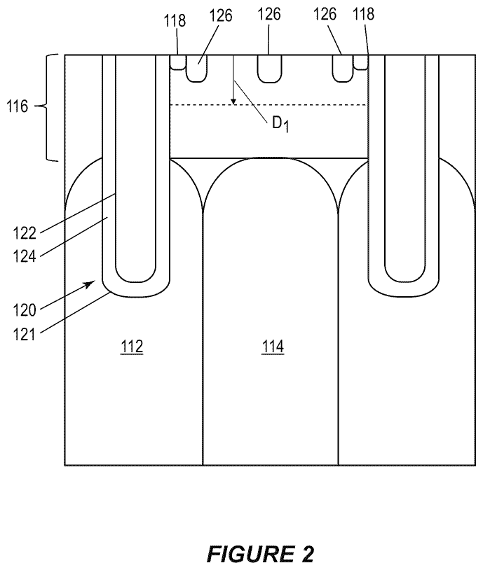

Referring to FIG. 2, a close-up of view of a transistor cell from the semiconductor device 100 is shown, according to an embodiment. The figure shows an area comprising the body layer 116 in between two of the gate trenches 121. According to an embodiment, the body layer 116 is configured such that a dopant profile of second conductivity type dopants in the body layer 116 increases moving from the main surface 104 into the semiconductor substrate 102 until it reaches a maximum at a first depth D₁ from the main surface 104. The vertical dopant profile of second conductivity refers to the absolute concentration of second conductivity type dopants extending in a vertical direction perpendicular to the main surface 104. In this embodiment, the second conductivity type dopants reach a peak concentration at the maximum and diminish in both vertical directions moving away from the maximum at first depth D₁.

According to an embodiment, the first depth D₁ is disposed below a bottom depth of the source regions 118. The bottom depth of the source regions 118 refers to the deepest location within the semiconductor substrate 102 comprising the first conductivity type dopants that are used to form the source regions 118. This arrangement of the second conductivity type dopant maximum of the body regions results from the body layer 116 implantation technique to be described in further detail below. This technique performs the body layer 116 implantation with an initial high energy implantation step that is performed before forming the gate trenches 121. This initial high energy implantation seeks to provide the maximum concentration of second conductivity dopants at a location corresponding to where the channel of the device forms. By way of comparison, previous techniques involve implanting dopant atoms for the body layer 116 after forming the gate trenches 121 and with lower implantation energy. In these techniques, annealing is used to diffuse the second conductivity type dopants from shallower locations to create the desired body region dopant concentration adjacent the gate trenches 121. In that case, the second conductivity type dopant maximum occurs closer to the surface of the substrate and not below the bottoms of the source regions 118.

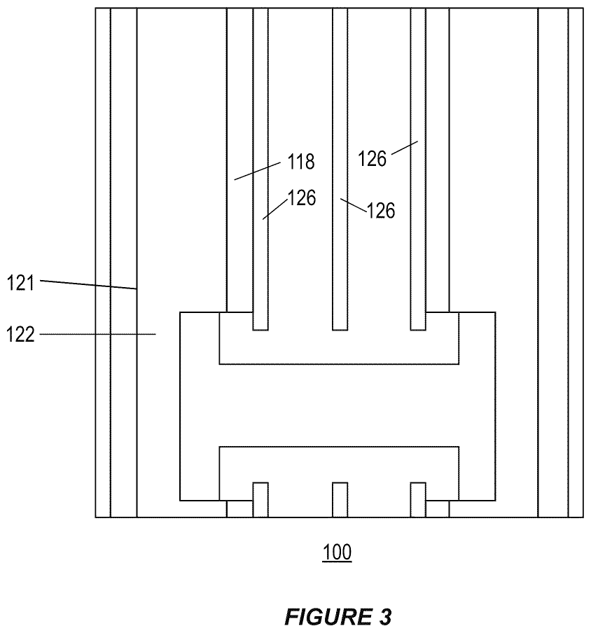

Referring to FIG. 3, a plan-view of a semiconductor device 100 is shown, according to an embodiment. As shown in the figure, the gate trenches 121 comprise elongated spans that run parallel to one another. These elongated spans may form a stripe-shaped pattern with each elongated gate trench corresponding to one of the transistor cells. Additionally, the semiconductor device 100 is configured with perpendicular spans of the gate trenches 121 that extend perpendicular to the elongated spans and form a connection between two immediately adjacent ones of the elongated spans. These perpendicular spans may be provided to improve the uniformity of the gate signal distribution.

FIG. 3 shows the plan-view layouts of the source regions 118 and the body enhancement regions 126 in the vicinity of the perpendicular spans of the gate trenches 121. As can be seen, the body enhancement regions 126, which have a higher second conductivity type dopant concentration than the body regions of the device, are extended past the source regions 118 and brought closer to the perpendicular spans of the gate trenches 121. By bringing the body enhancement regions 126 near the perpendicular, this raises the effective threshold voltage adjacent the perpendicular spans and corners between the perpendicular spans and the elongated spans. In embodiments, the body enhancement regions 126 may contact the perpendicular spans of the gate trenches 121. In particular, the body enhancement regions 126 may contact the and corners between the perpendicular spans and the elongated spans.

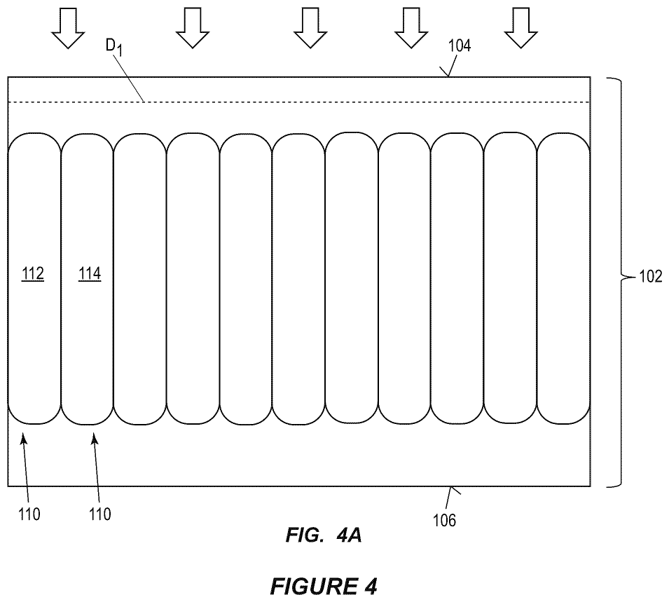

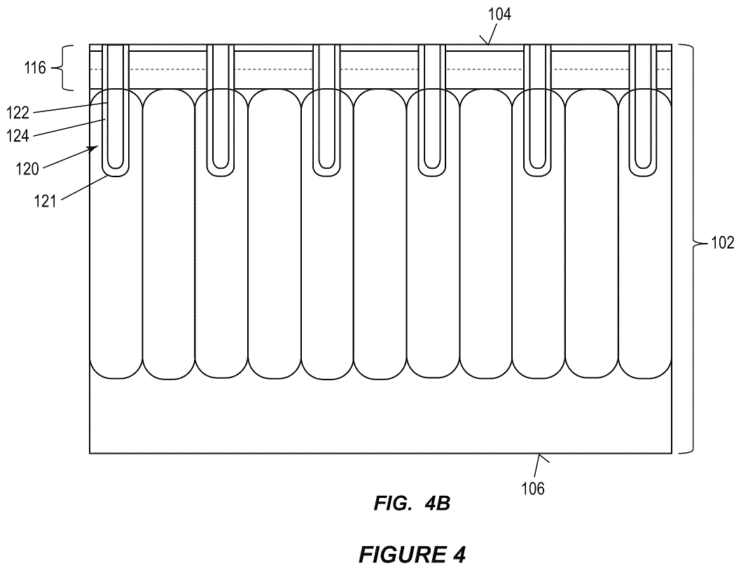

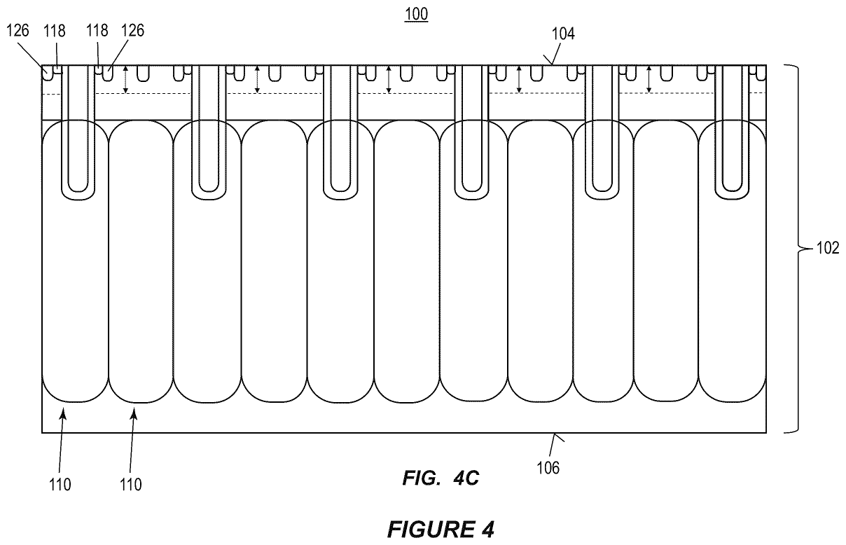

Referring to FIG. 4A, a method of forming the semiconductor device 100 comprises forming a semiconductor body 102 with a superjunction structure. As mentioned above, the superjunction structure may be formed by a multi-epi/multi-implant process, wherein multiple epitaxial layers are grown, dopants are implanted into surfaces of the epitaxial layers, and the process is repeated. Subsequently, an intrinsically doped epitaxial layer may be formed above the superjunction columns 110, thereby forming the semiconductor material up to the main surface 104 of the semiconductor body 102.

After providing the semiconductor body 102 with a superjunction structure, a first implantation step for forming the body layer 116 is performed. The first implantation step comprises an unmasked implantation of dopant atoms into the main surface 104 of the semiconductor body 102, wherein the dopant atoms used form second conductivity dopants in the semiconductor body 102. For example, the first implantation step may comprise implanting boron or gallium, which acts as a p-type dopant in silicon and other type IV semiconductor materials. The implantation energy of the first implantation step is selected such that the implanted dopant atoms nominally reach a target depth corresponding to the first depth D₁ wherein the dopant maximum of the body layer 116 exists as discussed above. Thus, after the first implantation step, the semiconductor substrate 102 comprises a high concentration of second conductivity dopants arranged substantially along a thin layer or plane within the semiconductor body 102 at the first depth D₁.

Referring to FIG. 4B, after performing the first implantation step, the gate structures 120 of the transistor cells are formed. Forming the gate structures 120 comprises forming gate trenches 121 that extend from the main surface 104 of the semiconductor substrate 102. This may be done by a masked etching technique, for example. Subsequently, a deposition step for forming a gate dielectric 124 in the gate trenches 121 is performed. For example, a dielectric material such as silicon dioxide (SiO₂), silicon nitride (SiN), or silicon oxynitride (SiO_{X}N_{Y}) may be deposited along the sidewalls of the gate trenches 121. Subsequently, a deposition step for forming gate electrodes 122 in the gate trenches 121 is performed. For example, a polysilicon layer may be deposited by a low-pressure chemical vapor deposition (LPCVD) tetraethyl orthosilicate (TEOS) process. A polishing step such as chemical mechanical polishing (CMP) may be performed to remove the deposited dielectric material and polysilicon material from the main surface 104 of the semiconductor body 102.

Referring to FIG. 4C, after forming the gate structures 120 of the transistor cells, further dopant implantation steps may be performed for forming the doped regions of the semiconductor device 100. In particular, a second implantation step may be performed after forming the gate trenches 121 to form the source regions 118. This second implantation step may comprise selectively implanting dopant atoms into areas corresponding to the location of the source regions 118, e.g., as described with reference to FIG. 2. The second implantation step may be performed by a masked implantation technique, for example. The dopant atoms implanted by the second implantation may be first conductivity type dopants in the semiconductor material of the semiconductor substrate 102, e.g., arsenic or phosphorous in the case of a silicon substrate. The target implantation depth of this second implantation step may be shallower than the implantation depth of the first implantation step. Thus, after dopant activation, a maximum concentration of the first conductivity type dopants from the source regions 118 occurs above the maximum concentration of the second conductivity type dopants from the body layer 116. Additionally, a third implantation step may be performed after forming the gate trenches 121 to form the body enhancement regions 126. This third implantation step may comprise selectively implanting dopant atoms the semiconductor material into areas corresponding to the location of the body enhancement regions 126. The third implantation step may be performed after forming body contact trenches such that the dopant atoms congregate just below the bottom of the body contacts. The dopant atoms implanted by the third implantation step may be second conductivity type dopants in the semiconductor material of the semiconductor substrate 102, e.g., boron or gallium in the case of a silicon semiconductor substrate 102.

After performing the second and third implantation steps, a number of thermal processing steps may be performed. These thermal processing steps may include one or more dedicated annealing steps that diffuse and activate dopant atoms. In particular a long duration annealing step may be performed at relatively lower temperatures and a rapid thermal annealing process may be performed at higher temperatures for much shorter duration. These thermal processing steps may additionally include deposition step for forming dielectric layers on a main surface 104 of the semiconductor substrate 102, e.g., passivation layers, interlayer dielectric layers, etc.

The above-described technique advantageously minimizes the thermal budget applied to the semiconductor substrate 102 after formation of the superjunction structure. In doing so, the technique facilitates higher cell pitch, i.e., a more closely spaced arrangement of the superjunction columns 110. By performing a high energy implantation step to implant the dopant atoms of the body layer 116 deeper into the semiconductor body 102 before formation of the gate trenches 121, subsequent thermal processing steps that are simultaneously used to form additional features of the semiconductor device 100, i.e., features other than the body layer 116, can be used to activate and outdiffuse the body layer 116 dopant atoms, thereby making efficient use of the thermal budget. In particular, the dopant atoms implanted by the first implantation step may be activated and outdiffused at least in part by the deposition steps for forming the gate dielectric 124 and the gate electrode 122. Additional thermal processing steps performed after the formation of the gate structures 120 may also contribute to the diffusion and activation of the body layer 116 dopant atoms. These additional thermal processing steps may include annealing steps performed after the second and third implantation steps, whereby dopant atoms from each of these implantation steps are diffused and activated simultaneously. These additional thermal processing steps may also include subsequent thermal processing steps, such as thermal deposition steps for forming dielectric layers on the main surface 104 of the semiconductor substrate 102, e.g., passivation layers, interlayer dielectrics, etc.

The above-described technique can advantageously maintain the thermal budget applied to the semiconductor substrate 102 after formation of the superjunction structure to no greater than 1050° C., or no greater than 1100° C., or equivalent thermal budget amounts. Below is an exemplary description of the thermal processing steps that may be performed after performing the first implantation step while maintaining the thermal budget within this constraint. A sacrificial oxide layer may be formed (and subsequently removed) by a thermal oxidation process that is performed at a temperature of no greater than 1000° C. and about 950° C. in an embodiment, for a duration no greater than 180 minutes. The gate dielectric 124 may be formed by a two-step process wherein a relatively thin, e.g., between 5-10 nm thick, layer of silicon dioxide is deposited by a thermal oxidation process that is performed, and further thickness, e.g., between 75-125 nm thick layer silicon dioxide is formed by a low-pressure chemical vapor deposition (LPCVD) tetraethyl orthosilicate (TEOS) process. The gate dielectric 124 may be compressed by an annealing step that is performed at a temperature of about 1000° C. Subsequently, the gate polysilicon may be formed by an LPCVD or plasma-enhanced chemical vapor deposition (PECVD) that is performed at a temperature of between about 550° C. and 650° C., for example. After the second and third implantation processes, a long duration annealing step may be performed at a temperature of about 90° C. s, and a rapid thermal annealing step may be performed at a temperature of about 1050° C.

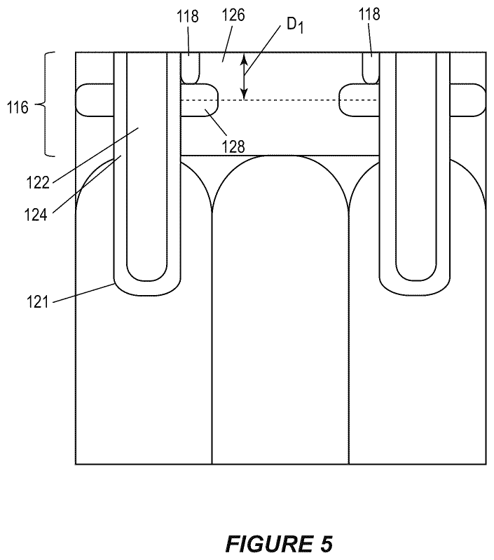

Referring to FIG. 5, a close-up of view of a transistor cell from the semiconductor device 100 is shown, according to another embodiment. Similar to the previously described embodiment, the body layer 116 is configured with a dopant maximum at first depth D1 from the main surface 104 that is below the bottom depth of the source regions 118 and below the body contacts of the device. However, the body layer 116 is created differently and has different lateral doping characteristics as the previously described device. In particular, the body layer 116 has a relatively higher baseline second conductivity type doping throughout the body layer 116. The baseline second conductivity type doping may be on the order of 1×10¹⁸ dopant atoms/cm³, for example. Additionally, partially compensated regions 128 are provided within the body region wherein the baseline second conductivity type doping is partially compensated by first conductivity type dopants. That is, the partially compensated regions 128 comprise both first conductivity type dopants and second conductivity type dopants, with a lower concentration of first conductivity type dopants than second conductivity type dopants. The partially compensated regions 128 may comprise a net second conductivity type dopant concentration on the order of 1×10¹⁴ dopant atoms/cm³ to 1×10¹⁶ dopant atoms/cm³, for example.

The body enhancement regions 126 of the semiconductor device 100 are formed by portions of the body layer 116 having the baseline second conductivity type doping. That is, due to the baseline second conductivity type doping of the body layer 116, the body contact trenches can make direct contact with P+ or P++ material. The body regions of the device adjacent to the gate trenches 121 are formed by the partially compensated regions 128 of the body layer 116 wherein the net second conductivity type dopant concentration of the is lower than the baseline second conductivity type doping of the body layer 116. This creates the necessary threshold voltage for the semiconductor device 100, as the device channel may form in regions with the lower second conductivity type dopant concentrations.

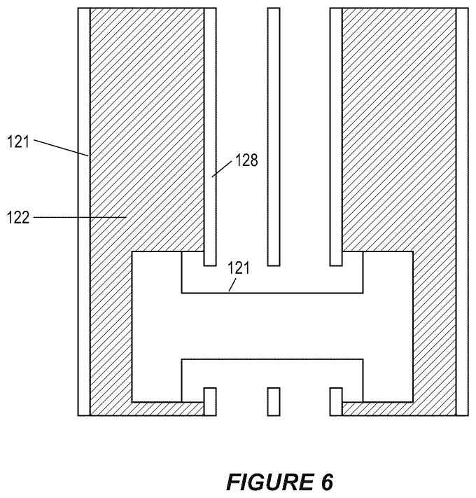

Referring to FIG. 6, a plan-view of a semiconductor device 100 is shown, according to an embodiment. The plan-view corresponds to the plan-view shown in FIG. 3, with perpendicular spans of the gate trenches 121 extending between the elongated spans of the gate trenches 121 that run parallel to one another. As can be seen, the partially compensated regions 128 of the body layer 116 are formed along the sidewalls of the gate trenches 121, thereby forming the necessary operating voltage of the device. Meanwhile, the body layer 116 with the baseline second conductivity type doping directly adjoins the perpendicular spans. That is, the perpendicular spans of the gate trenches 121 and sections of the elongated spans forming corners with the perpendicular spans do not adjoin the compensated regions and instead adjoin material with the relatively higher baseline second conductivity type doping concentration. Thus, the threshold voltage is increased in these areas in a similar manner as described above.

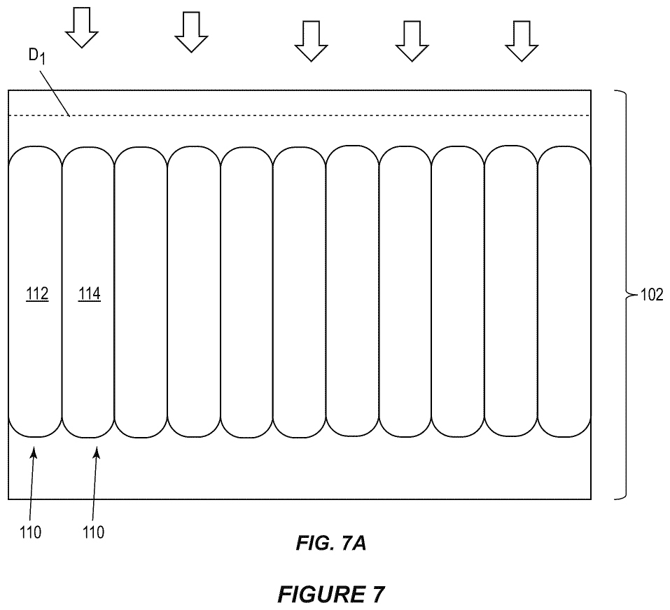

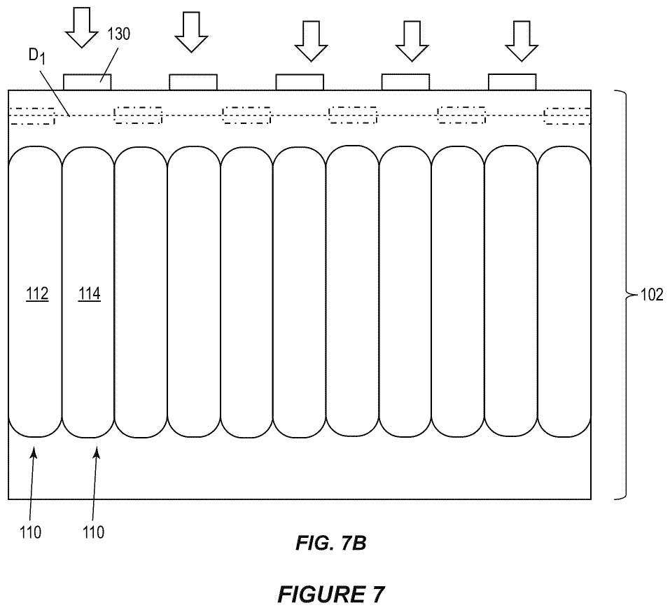

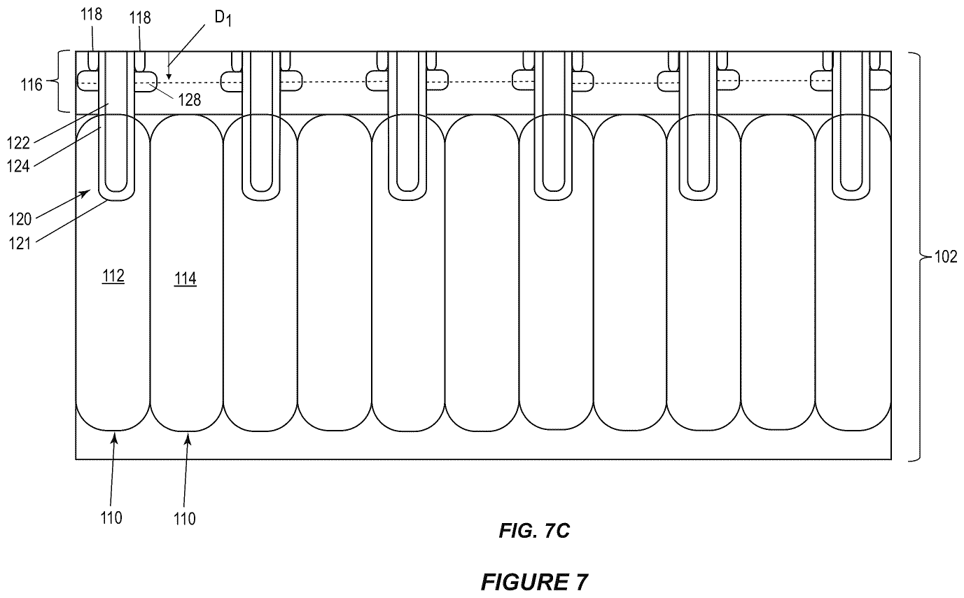

Referring to FIG. 7, selected method steps for forming the semiconductor device 100 described with reference to FIGS. 5 and 6 are shown, according to an embodiment.

Referring to FIG. 7A, a semiconductor body 102 comprising a superjunction structure is provided. Subsequently, a first pre-gate implantation step for forming the body layer 116 is performed before forming the gate trenches 121. The pre-gate formation implantation step comprises implanting dopant atoms that have the second conductivity type in the semiconductor body 102 to a target depth. The first pre-gate implantation step may be identical to the first implantation step described with reference to FIG. 4A, except that the dopant dosage is higher. In this case, the dopant dosage is selected to create a baseline second conductivity type doping in the body layer 116 as a highly doped region, e.g., a P+ or P++ region. For example, the initial body layer 116 implantation step may comprise an implantation dosage in the range of between of 1×10¹⁵ dopant atoms/cm² to 1×10¹⁶ dopant atoms/cm².

Referring to FIG. 7B, a second pre-gate implantation step is performed after the first pre-gate implantation step and before forming the plurality of gate trenches 121. The second pre-gate implantation step is a masked implantation step that implants dopant atoms in regions wherein the gate trenches 121 are to be formed. That is, the second pre-gate implantation step comprises forming a patterned mask 130 over the suberate with openings that are centered with respect to the locations wherein the gate trenches 121 are to be formed. The width of the openings in the mask may is greater than the width of the gate trenches 121 to be formed so as to create the partially compensated regions 128 adjacent the gate trenches 121. The implant energy is selected such that the dopant atoms of the second pre-gate implantation step are implanted to the same target depth as the first pre-gate implantation step. The dosage of second pre-gate implantation step is lower than the dosage of the first pre-gate implantation step. For example, the second pre-gate implantation step may comprise an implantation dosage on the order of 1×10¹² dopant atoms/cm² to 1×10¹³ dopant atoms/cm². As a result, in the location of where the gate regions are to be formed, the semiconductor substrate 102 comprises a concentration of the first conductivity type dopants and a lower concentration of the second conductivity type dopants.

FIG. 7C shows the semiconductor device 100 after formation of the gate structures 120 and subsequent formation of the source regions 118, followed by dopant activation. The methods used to form these features may be identical to those described with reference to FIGS. 4B and 4C, except that the fourth implantation step for forming the highly doped body regions may be omitted. Because this technique forms the body layer 116 with a baseline second conductivity type doping throughout the body layer 116 corresponding to the dopant concentration needed for the body enhancement regions 126, a specific step for forming the highly doped body regions after gate trench formation is not needed. This advantageously lowers the time and expense of manufacture, as the doping step for forming the body enhancement regions 126 can be costly and time consuming.

Although the present disclosure is not so limited, the following numbered examples demonstrate one or more aspects of the disclosure.

Example 1. A method of forming a semiconductor device, the method comprising: forming a semiconductor substrate with a superjunction structure, the superjunction structure comprising a plurality of superjunction columns that alternate in conductivity type along a lateral direction of the semiconductor substrate; and forming a plurality of transistor cells in an active area of the semiconductor substrate, each of the transistor cells being configured to control a vertical current flowing through the superjunction structure, wherein forming the transistor cells comprises forming first load terminal regions extending to a main surface of the semiconductor substrate and body regions at least partially below the first load terminal regions, the first load terminal regions being first conductivity type regions and the body regions being second conductivity type regions; wherein forming the body regions comprises forming a body layer extending from a main surface of the semiconductor substrate, wherein a dopant profile of second conductivity type dopants in the body layer increases moving from the main surface into the semiconductor substrate until it reaches a maximum at first depth from the main surface, and wherein the first depth is below a bottom depth of the first load terminal regions.

Example 2. The method of example 1, wherein forming the body layer comprises performing a first implantation step and activating and outdiffusing dopant atoms implanted by the first implantation step, and wherein activating dopant atoms implanted by the first implantation step is done by one or more thermal processing steps that are simultaneously used to form additional features of the semiconductor device.

Example 3. The method of example 2, wherein forming the plurality of transistor cells comprises forming gate trenches that extend into the main surface of the semiconductor substrate, wherein the first implantation step is performed before forming the gate trenches.

Example 4. The method of example 3, wherein the one or more thermal processing steps that are simultaneously used to form additional features of the semiconductor device are performed after forming the gate trenches.

Example 5. The method of example 4, wherein the one or more thermal processing steps that are simultaneously used to form additional features of the semiconductor device comprise any one of: a thermal oxidation step for forming a gate dielectric in the gate trenches; a recrystallization step after depositing the material for forming gate electrodes in the gate trenches; and an annealing step for forming a sacrificial oxide that is performed after forming the gate trenches.

Example 6. The method of example 3, wherein forming the first load terminal regions comprises performing a second implantation step after forming the gate trenches, and wherein the thermal processing steps that are performed after forming the gate trenches comprise an annealing step that simultaneously activates and diffuses the dopant atoms implanted by the first and second implantation steps.

Example 7. The method of example 3, further comprising: forming body enhancement regions within the body layer, the body enhancement regions having a higher second conductivity type dopant concentration than the body regions; and forming body contacts in ohmic contact with the body enhancement regions, wherein the first depth is below bottom sides of the body contacts.

Example 8. The method of example 1, wherein the gate trenches are formed to comprise elongated spans that run parallel to one another and perpendicular spans that extend perpendicular to the elongated spans and form a connection between two immediately adjacent ones of the elongated spans, and wherein the body enhancement regions 126 extend closer to the perpendicular spans than the first load terminal regions.

Example 9. A semiconductor device, comprising: a semiconductor substrate with a superjunction structure, the superjunction structure comprising a plurality of superjunction columns that alternate in conductivity type along a lateral direction of the semiconductor substrate; and a plurality of transistor cells in an active area of the semiconductor substrate, each of the transistor cells being configured to control a vertical current flowing through superjunction structure, wherein the transistor cells each comprise first load terminal regions extending to a main surface of the semiconductor substrate and body regions at least partially below the first load terminal regions, the first load terminal regions being first conductivity type regions and the body regions being second conductivity type regions; wherein for each of the body regions a dopant profile of second conductivity type dopants increases moving from the main surface into the semiconductor substrate until it reaches a maximum at first depth from the main surface, and wherein the first depth is below a bottom depth of the first load terminal regions.

Example 10. The semiconductor device of example 9, wherein the semiconductor device comprises a body layer that extends to the main surface, wherein the body regions are formed by the body layer, and wherein the semiconductor device further comprises: body enhancement regions that are formed within the body layer and extend to the main surface, the body enhancement regions having a higher second conductivity type dopant concentration than the body regions; and body contacts in ohmic contact with the body enhancement regions, wherein the first depth is below bottom sides of the body contacts.

Example 11. The semiconductor device of example 10, wherein the transistor cells each comprise gate trenches, wherein the gate trenches comprise elongated spans that run parallel to one another and perpendicular spans that extend perpendicular to the elongated spans and form a connection between two immediately adjacent ones of the elongated spans, and wherein the body enhancement regions extend closer to the perpendicular spans than the first load terminal regions.

Example 12. A method of forming a semiconductor device, the method comprising: forming a semiconductor substrate with a superjunction structure, the superjunction structure comprising a plurality of superjunction columns that alternate in conductivity type along a lateral direction of the semiconductor substrate; and forming a plurality of transistor cells in an active area of the semiconductor substrate, each of the transistor cells being configured to control a vertical current flowing through superjunction structure, wherein forming the transistor cells comprises forming a plurality of gate trenches in a main surface of the semiconductor substrate, forming body regions adjacent the gate trenches, and forming body enhancement regions that are laterally spaced apart from the gate trenches, the body enhancement regions having a higher second conductivity type dopant concentration than the body regions, wherein forming the body regions and forming the body enhancement regions comprises forming a body layer that extends from the main surface into the semiconductor substrate and has a baseline second conductivity type doping throughout the body layer and forming partially compensated regions of the body layer wherein the baseline second conductivity type doping is partially compensated by first conductivity type dopants, wherein the body enhancement regions are provided by uncompensated parts of the body layer having the baseline second conductivity type doping, and wherein the body regions are formed by the partially compensated regions of the body layer.

Example 13. The method of example 12, wherein forming the body layer comprises performing a first pre-gate formation implantation step before forming the plurality of gate trenches, wherein a dopant dose of the first pre-gate-formation implantation step is selected to create the baseline second conductivity type doping in the body layer.

Example 14. The method of example 13, wherein forming partially compensated regions of the body layer comprises performing a second pre-gate-formation implantation step after the first pre-gate-formation implantation step and before forming the plurality of gate trenches, wherein the second pre-gate-formation implantation step is a masked implantation step that implants first conductivity type dopants in regions wherein the gate trenches are to be formed.

Example 15. The method of example 14, wherein the first pre-gate-formation implantation step and the second pre-gate-formation implantation step each implant dopant atoms to a first target depth below the main surface of the semiconductor substrate.

Example 16. The method of example 15, further comprising activating the dopant atoms implanted by the first pre-gate-formation implantation step and the second pre-gate-formation implantation step after forming the gate trenches, and wherein activating dopant atoms implanted by the first pre-gate-formation implantation step and the second pre-gate-formation implantation step is done by one or more thermal processing steps that are simultaneously used to form additional features of the semiconductor device.

Example 17. The method of example 12, wherein forming the transistor cells comprises forming first load terminal regions extending to a main surface of the semiconductor substrate, wherein a dopant profile of second conductivity type dopants in the body layer increases moving from the main surface into the semiconductor substrate until it reaches a maximum at first depth from the main surface, and wherein the first depth is below a bottom depth of the first load terminal regions.

Example 18. The method of example 17, further comprising forming body contacts in ohmic contact with the body enhancement regions, wherein the first depth is below bottom sides of the body contacts.

Example 19. The method of example 12, wherein the gate trenches are formed to comprise elongated spans that run parallel to one another and perpendicular spans that extend perpendicular to the elongated spans and form a connection between two immediately adjacent ones of the elongated spans.

Example 20. The method of example 19, wherein the body layer with the baseline second conductivity type doping directly adjoins the perpendicular spans.

Example 21. A semiconductor device, comprising: a semiconductor substrate with a superjunction structure, the superjunction structure comprising a plurality of superjunction columns that alternate in conductivity type along a lateral direction of the semiconductor substrate; and a plurality of transistor cells in an active area of the semiconductor substrate, each of the transistor cells being configured to control a vertical current flowing through superjunction structure, a body layer extending from a main surface of the semiconductor substrate in the active area and having a baseline second conductivity type doping; wherein the transistor cells comprise a plurality of gate trenches in a main surface of the semiconductor substrate, body regions adjacent the gate trenches, and body enhancement regions that are laterally spaced apart from the gate trenches, the body enhancement regions having a higher second conductivity type dopant concentration than the body regions, wherein the body enhancement regions are formed by portions of the body layer having the baseline second conductivity type doping, and wherein the body regions are formed by partially compensated regions of the body layer wherein the baseline second conductivity type doping is partially compensated by first conductivity type dopants.

Example 22. The semiconductor device of example 21, wherein a dopant profile of second conductivity type dopants in the body layer comprises a maximum at first depth from the main surface, and wherein a dopant profile of first conductivity type dopants in the partially compensated regions of the body layer comprises a maximum at the first depth from the main surface.

Example 23. The semiconductor device of example 22, wherein the transistor cells comprise first load terminal regions extending to a main surface of the semiconductor substrate, and wherein the first depth is below a bottom depth of the first load terminal regions.

Example 24. The semiconductor device of example 22, wherein the semiconductor device further comprises body contacts in ohmic contact with the body enhancement regions, wherein the first depth is below bottom sides of the body contacts.

Example 25. The semiconductor device of example 21, wherein the gate trenches comprise elongated spans that run parallel to one another and perpendicular spans that extend perpendicular to the elongated spans and form a connection between two immediately adjacent ones of the elongated spans.

Example 26. The semiconductor device of example 25, wherein the body layer with the baseline second conductivity type doping directly adjoins the perpendicular spans.

The present specification refers to a “first” and a “second” conductivity type of dopants, semiconductor portions are doped with. The first conductivity type may be n type and the second conductivity type may be p type or vice versa. As is generally known, depending on the doping type or the polarity of the source and drain regions, insulated gate field effect transistors (IGFETs) such as metal oxide semiconductor field effect transistors (MOSFETs) may be n-channel or p-channel MOSFETs. For example, in an n-channel MOSFET, the source and the drain region are doped with n-type dopants. In a p-channel MOSFET, the source and the drain region are doped with p-type dopants. As is to be clearly understood, within the context of the present specification, the doping types may be reversed. If a specific current path is described using directional language, this description is to be merely understood to indicate the path and not the polarity of the current flow, i.e., whether the current flows from source to drain or vice versa. The Figures may include polarity-sensitive components, e.g., diodes. As is to be clearly understood, the specific arrangement of these polarity-sensitive components is given as an example and may be inverted in order to achieve the described functionality, depending whether the first conductivity type means n-type or p-type.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the examples and their legal equivalents.

1. A method of forming a semiconductor device, the method comprising:
forming a semiconductor substrate with a superjunction structure, the superjunction structure comprising a plurality of superjunction columns that alternate in conductivity type along a lateral direction of the semiconductor substrate; and
forming a plurality of transistor cells in an active area of the semiconductor substrate, each of the transistor cells being configured to control a vertical current flowing through the superjunction structure,
wherein forming the transistor cells comprises forming first load terminal regions extending to a main surface of the semiconductor substrate and body regions at least partially below the first load terminal regions, the first load terminal regions being first conductivity type regions and the body regions being second conductivity type regions;
wherein forming the body regions comprises forming a body layer extending from a main surface of the semiconductor substrate,
wherein a dopant profile of second conductivity type dopants in the body layer increases moving from the main surface into the semiconductor substrate until it reaches a maximum at first depth from the main surface, and
wherein the first depth is below a bottom depth of the first load terminal regions.

2. The method of claim 1, wherein forming the body layer comprises performing a first implantation step and activating and outdiffusing dopant atoms implanted by the first implantation step, and wherein activating dopant atoms implanted by the first implantation step is done by one or more thermal processing steps that are simultaneously used to form additional features of the semiconductor device.

3. The method of claim 2, wherein forming the plurality of transistor cells comprises forming gate trenches that extend into the main surface of the semiconductor substrate, wherein the first implantation step is performed before forming the gate trenches.

4. The method of claim 3, wherein the one or more thermal processing steps that are simultaneously used to form additional features of the semiconductor device are performed after forming the gate trenches.

5. The method of claim 4, wherein the one or more thermal processing steps that are simultaneously used to form additional features of the semiconductor device comprise any one of:
a thermal oxidation step for forming a gate dielectric in the gate trenches;
a recrystallization step after depositing the material for forming gate electrodes in the gate trenches; and
an annealing step for forming a sacrificial oxide that is performed after forming the gate trenches.

6. The method of claim 3, wherein forming the first load terminal regions comprises performing a second implantation step after forming the gate trenches, and wherein the thermal processing steps that are performed after forming the gate trenches comprise an annealing step that simultaneously activates and outdiffuses the dopant atoms implanted by the first and second implantation steps.

7. The method of claim 3, further comprising:
forming body enhancement regions within the body layer, the body enhancement regions having a higher second conductivity type dopant concentration than the body regions; and
forming body contacts in ohmic contact with the body enhancement regions,
wherein the first depth is below bottom sides of the body contacts.

8. The method of claim 7, wherein the gate trenches are formed to comprise elongated spans that run parallel to one another and perpendicular spans that extend perpendicular to the elongated spans and form a connection between two immediately adjacent ones of the elongated spans, and wherein the body enhancement regions extend closer to the perpendicular spans than the first load terminal regions.

9. A semiconductor device, comprising:
a semiconductor substrate with a superjunction structure, the superjunction structure comprising a plurality of superjunction columns that alternate in conductivity type along a lateral direction of the semiconductor substrate; and
a plurality of transistor cells in an active area of the semiconductor substrate, each of the transistor cells being configured to control a vertical current flowing through superjunction structure,
wherein the transistor cells each comprise first load terminal regions extending to a main surface of the semiconductor substrate and body regions at least partially below the first load terminal regions, the first load terminal regions being first conductivity type regions and the body regions being second conductivity type regions;
wherein for each of the body regions a dopant profile of second conductivity type dopants increases moving from the main surface into the semiconductor substrate until it reaches a maximum at first depth from the main surface, and
wherein the first depth is below a bottom depth of the first load terminal regions.

10. The semiconductor device of claim 9, wherein the semiconductor device comprises a body layer that extends to the main surface, wherein the body regions are formed by the body layer, and wherein the semiconductor device further comprises:
body enhancement regions that are formed within the body layer and extend to the main surface, the body enhancement regions having a higher second conductivity type dopant concentration than the body regions; and
body contacts in ohmic contact with the body enhancement regions, wherein the first depth is below bottom sides of the body contacts.

11. The semiconductor device of claim 10, wherein the transistor cells each comprise gate trenches, wherein the gate trenches comprise elongated spans that run parallel to one another and perpendicular spans that extend perpendicular to the elongated spans and form a connection between two immediately adjacent ones of the elongated spans, and wherein the body enhancement regions extend closer to the perpendicular spans than the first load terminal regions.

12. A method of forming a semiconductor device, the method comprising:
forming a semiconductor substrate with a superjunction structure, the superjunction structure comprising a plurality of superjunction columns that alternate in conductivity type along a lateral direction of the semiconductor substrate; and
forming a plurality of transistor cells in an active area of the semiconductor substrate, each of the transistor cells being configured to control a vertical current flowing through superjunction structure,
wherein forming the transistor cells comprises forming a plurality of gate trenches in a main surface of the semiconductor substrate, forming body regions adjacent the gate trenches, and forming body enhancement regions adjacent to the body regions, the body enhancement regions having a higher second conductivity type dopant concentration than the body regions,
wherein forming the body regions and forming the body enhancement regions comprises forming a body layer that extends from the main surface into the semiconductor substrate and has a baseline second conductivity type doping throughout the body layer and forming partially compensated regions of the body layer wherein the baseline second conductivity type doping is partially compensated by first conductivity type dopants,
wherein the body enhancement regions are provided by uncompensated parts of the body layer having the baseline second conductivity type doping, and
wherein the body regions are formed by the partially compensated regions of the body layer.

13. The method of claim 12, wherein forming the body layer comprises performing a first pre-gate formation implantation step before forming the plurality of gate trenches, wherein a dopant dose of the first pre-gate formation implantation step is selected to create the baseline second conductivity type doping in the body layer.

14. The method of claim 13, wherein forming partially compensated regions of the body layer comprises performing a second pre-gate-formation implantation step after the first pre-gate-formation implantation step and before forming the plurality of gate trenches, wherein the second pre-gate-formation implantation step is a masked implantation step that implants first conductivity type dopants in regions wherein the gate trenches are to be formed.

15. The method of claim 14, wherein the first pre-gate-formation implantation step and the second pre-gate-formation implantation step each implant dopant atoms to a first target depth below the main surface of the semiconductor substrate.

16. The method of claim 15, further comprising activating the dopant atoms implanted by the first pre-gate-formation implantation step and the second pre-gate-formation implantation step after forming the gate trenches, and wherein activating dopant atoms implanted by the first pre-gate-formation implantation step and the second pre-gate-formation implantation step is done by one or more thermal processing steps that are simultaneously used to form additional features of the semiconductor device.

17. The method of claim 12, wherein forming the transistor cells comprises forming first load terminal regions extending to a main surface of the semiconductor substrate, wherein a dopant profile of second conductivity type dopants in the body layer increases moving from the main surface into the semiconductor substrate until it reaches a maximum at first depth from the main surface, and wherein the first depth is below a bottom depth of the first load terminal regions.

18. The method of claim 17, further comprising forming body contacts in ohmic contact with the body enhancement regions, wherein the first depth is below bottom sides of the body contacts.

19. The method of claim 12, wherein the gate trenches are formed to comprise elongated spans that run parallel to one another and perpendicular spans that extend perpendicular to the elongated spans and form a connection between two immediately adjacent ones of the elongated spans.

20. The method of claim 19, wherein the body layer with the baseline second conductivity type doping directly adjoins the perpendicular spans.

21. A semiconductor device, comprising:
a semiconductor substrate with a superjunction structure, the superjunction structure comprising a plurality of superjunction columns that alternate in conductivity type along a lateral direction of the semiconductor substrate; and
a plurality of transistor cells in an active area of the semiconductor substrate, each of the transistor cells being configured to control a vertical current flowing through superjunction structure,
a body layer extending from a main surface of the semiconductor substrate in the active area and having a baseline second conductivity type doping;
wherein the transistor cells comprise a plurality of gate trenches in a main surface of the semiconductor substrate, body regions adjacent the gate trenches, and body enhancement regions adjacent the body regions, the body enhancement regions having a higher second conductivity type dopant concentration than the body regions,
wherein the body enhancement regions are formed by portions of the body layer having the baseline second conductivity type doping, and
wherein the body regions are formed by partially compensated regions of the body layer wherein the baseline second conductivity type doping is partially compensated by first conductivity type dopants.

22. The semiconductor device of claim 21, wherein a dopant profile of second conductivity type dopants in the body layer comprises a maximum at first depth from the main surface, and wherein a dopant profile of first conductivity type dopants in the partially compensated regions of the body layer comprises a maximum at the first depth from the main surface.

23. The semiconductor device of claim 22, wherein the transistor cells comprise first load terminal regions extending to a main surface of the semiconductor substrate, and wherein the first depth is below a bottom depth of the first load terminal regions.

24. The semiconductor device of claim 22, wherein the semiconductor device further comprises body contacts in ohmic contact with the body contact regions, wherein the first depth is below bottom sides of the body contacts.

25. The semiconductor device of claim 21, wherein the gate trenches comprise elongated spans that run parallel to one another and perpendicular spans that extend perpendicular to the elongated spans and form a connection between two immediately adjacent ones of the elongated spans.

26. The semiconductor device of claim 25, wherein the body layer with the baseline second conductivity type doping directly adjoins the perpendicular spans.
